(19) United States
(12) Patent Application Publication
(10) Pub. No.: US 2006/0240587 A1
(43) Pub. Date: Oct. 26, 2006

(54) Transflective liquid crystal display and manufacturing method of the same

(76) Inventor: Young-Chol Yang, Seongnam-si (KR)

Correspondence Address: CANTOR COLBURN, LLP, 55 GRIFFIN ROAD SOUTH, BLOOMFIELD, CT, 06002, US

(21) Appl. No.: 11/370,107

(22) Filed: Mar. 7, 2006

(30) Foreign Application Priority Data
Apr. 22, 2005 (KR) 10-2005-0033507

(51) Int. Cl. H01L 21/00; H01L 29/04

(52) U.S. Cl. 438/30; 257/59

(57) ABSTRACT

A transflective liquid crystal display (LCD) is disclosed where the liquid crystal layer includes a transmission area and a reflective area. The ratio of the liquid crystal molecules to polymers in the reflection area is lower than in the transmission area through independent exposure of the two areas to light to polymerize monomers contained in the original liquid crystal layer mixture. Because of the varied ratios in the two areas of the liquid crystal layer, the two areas also possess different phase retardation values while possessing the same cell gap, and display an improved image over conventional transflective liquid crystal displays.

### CROSS REFERENCE TO RELATED APPLICATION

This application claims priority to and the benefit of Korean Patent Application No. 10-2005-0033507, filed on Apr. 22, 2005, which is hereby incorporated by reference for all purposes as if fully set forth herein.

### BACKGROUND OF THE INVENTION

1. Field of the Invention

The present invention relates to a transflective liquid crystal display in which transmission areas and reflection areas have different phase retardation values, while having the same cell gaps, and a method of manufacturing the same.

2. Discussion of the Background

Presently, liquid crystal displays (LCDs) are widely used as flat panel display devices. An LCD includes two panels with electrodes mounted on their inner surfaces, and a dielectric anisotropy liquid crystal layer interposed between the panels. In an LCD, a change in the voltage difference between the electrodes mounted on the panels changes the transmittance of the light passing through the LCD. Thus, desired images on the LCD are obtained by controlling the voltage difference between the electrodes.

Depending on the kind of light source used for image display, LCDs are divided into three types: transmissive, reflective, and transreflective. In transmissive LCDs, pixels are illuminated from behind the panels by a backlight. In reflective LCDs, the pixels are illuminated from the front using incident light originating from the ambient environment. Transreflective LCDs combine transmissive and reflective characteristics. Under medium light conditions, such as an indoor environment, or dark conditions, these LCDs operate in a transmissive mode. Under bright conditions, such as a daytime outdoor environment, they operate in a reflective mode.

In a transreflective LCD, there are both transmission areas and reflection areas. In the reflection areas exterior light passes through the liquid crystal layer twice: once as the light enters the panel, and once when the light reflects and exits the panel. In the transmission areas, light emitted from the backlight provided behind an LCD panel assembly passes through the liquid crystal layer only once. Because the light passes through the panel differently in the two regions, the phase retardation values of the transmission areas and the reflection areas must be different to project the desired image properly.

One possible method for controlling the retardation values of the two layers is to form different cell gaps for the transmission areas and the reflection areas. However, an additional manufacturing step is necessary to form a relatively thick organic layer prior to the formation of the reflective electrodes. In addition, problematic alignment of the liquid crystal layer, such as disclination, or incidental images may result due to large stage difference at the borders of the transmission areas and the reflection areas.

### SUMMARY OF THE INVENTION

This invention provides a transflective liquid crystal display, in which transmission areas and reflection areas have different phase retardation values but the same cell gaps, and a method of manufacturing the same.

Additional features of the invention will be set forth in the description which follows, and in part will be apparent from the description, or may be learned by practice of the invention.

The present invention discloses a transflective liquid crystal display comprising a first substrate, a gate line formed on the first substrate, a data line insulated from and intersecting the gate line, a thin film transistor coupled to the gate line and data line, a transparent electrode coupled to the thin film transistor, a reflective electrode formed on the transparent electrode, a second substrate opposite the first substrate with a common electrode, and a liquid crystal layer comprised of a mixture of liquid crystal molecules and polymers. The liquid crystal layer is interposed between the first and second substrate. A reflection area is formed around the reflective electrode, a transmission area is formed around the transparent electrode, and the ratio of the liquid crystal molecules to the polymers contained in the liquid crystal layer is different in the transmission area and the reflection area

The present invention also discloses a method for manufacturing a transflective liquid crystal display, where the method comprises forming a gate line on a first substrate, forming a gate insulating layer and a semiconductor on the gate line, forming a data line on the gate insulating layer and the semiconductor, forming a transparent electrode on the data lines, forming a reflective electrode on the transparent electrodes, forming a color filter and a common electrode on a second substrate, assembling the first substrate and the second substrate, injecting a mixture of liquid crystal molecules and monomers between the first substrate and the second substrate, exposing the reflective electrode and the mixture around the reflective electrode to light, and then exposing the transparent electrode and the mixture around the transparent electrode to light.

The present invention also discloses a liquid crystal layer of a liquid crystal display, where the liquid crystal layer comprises a liquid crystal molecules and polymers, where the ratio of the liquid crystal molecules to the polymers contained in an area around a transparent electrode is higher than in an area around a reflective electrode.

It is to be understood that both the foregoing general description and the following detailed description are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this specification, illustrate embodiments of the invention, and together with the description serve to explain the principles of the invention.

FIG. 1 shows a layout view of an LCD according to an embodiment of the present invention.

FIG. 2 shows a schematic cross-sectional view cut along II-II′ of FIG. 1.

FIG. 3, FIG. 4, FIG. 5, FIG. 6, FIG. 7, FIG. 8, FIG. 9, FIG. 10, and FIG. 11 show schematic cross-sectional views cut along II-II′ of FIG. 1 through the process steps to manufacture a transflective LCD according to an embodiment of the present invention.

### DETAILED DESCRIPTION OF THE ILLUSTRATED EMBODIMENTS

The invention is described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure is thorough, and will fully convey the scope of the invention to those skilled in the art. In the drawings, the size and relative sizes of layers and regions may be exaggerated for clarity.

It will be understood that when an element such as a layer, film, region or substrate is referred to as being “on” another element, it can be directly on the other element or intervening elements may also be present. In contrast, when an element is referred to as being “directly on” another element, there are no intervening elements present. In the following description and drawings, the same reference numerals refer to the same components, and repetitive description has been omitted.

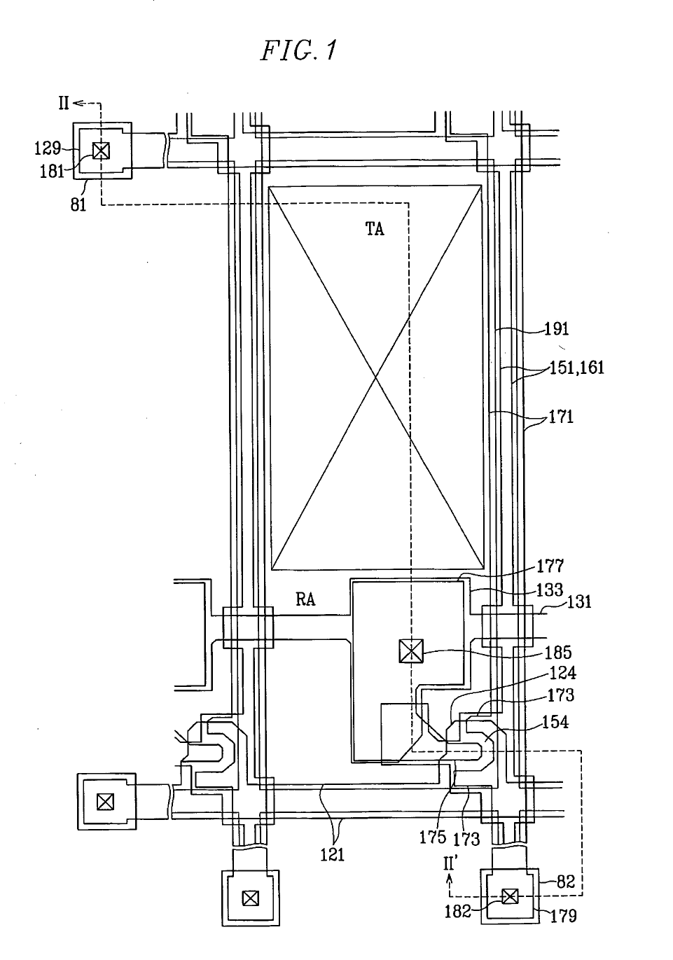

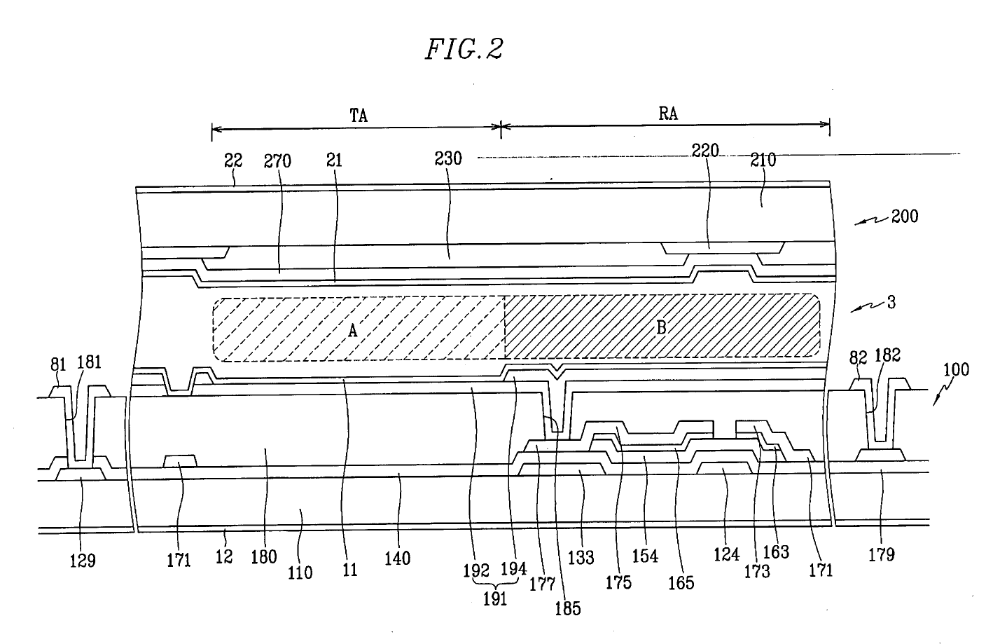

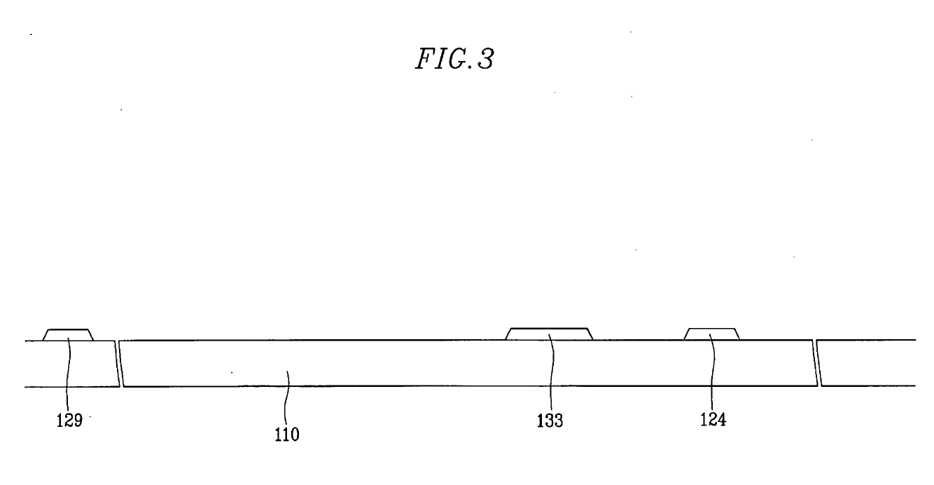

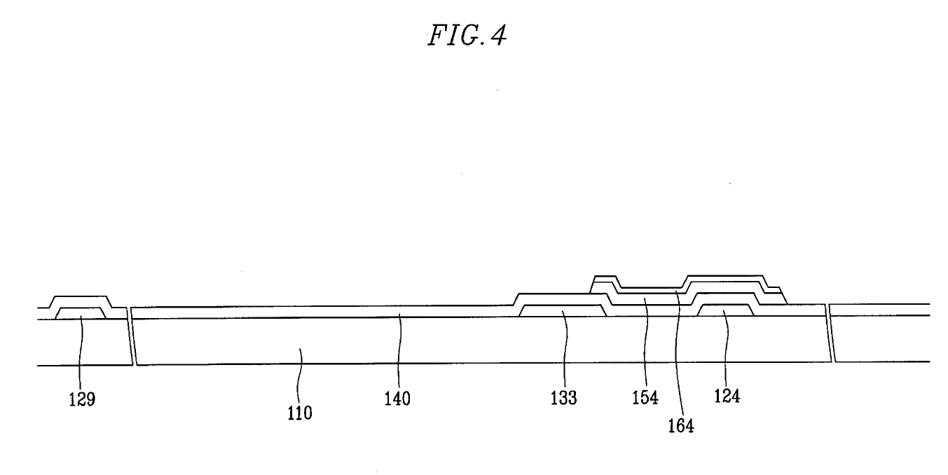

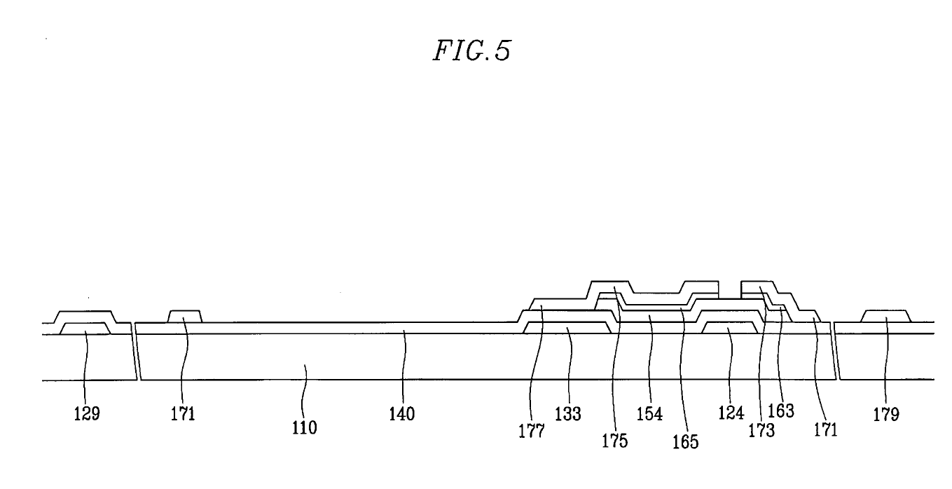

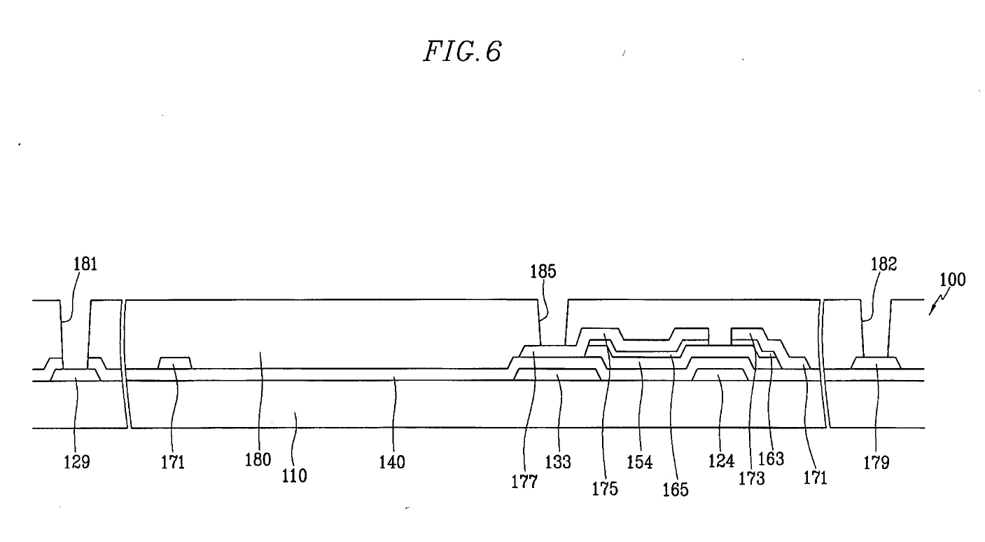

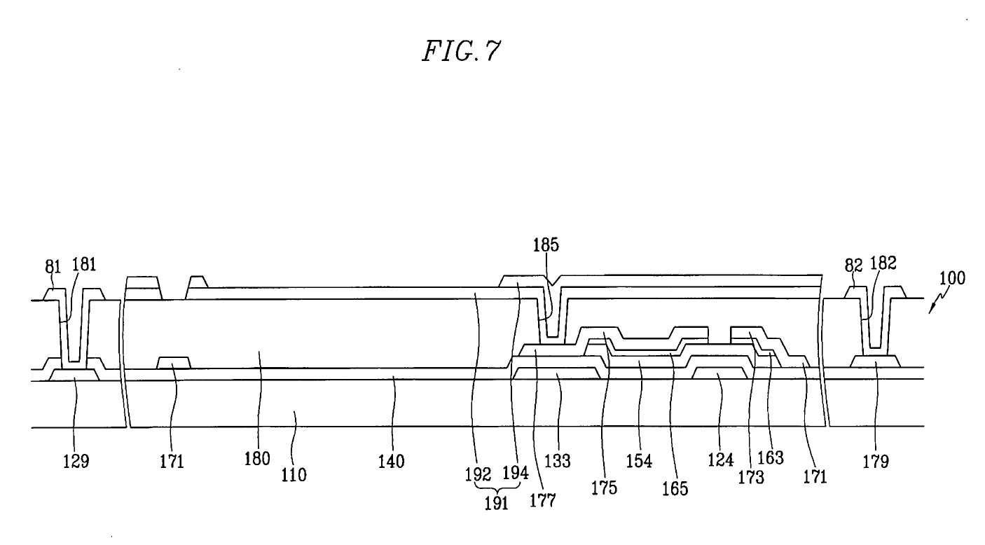

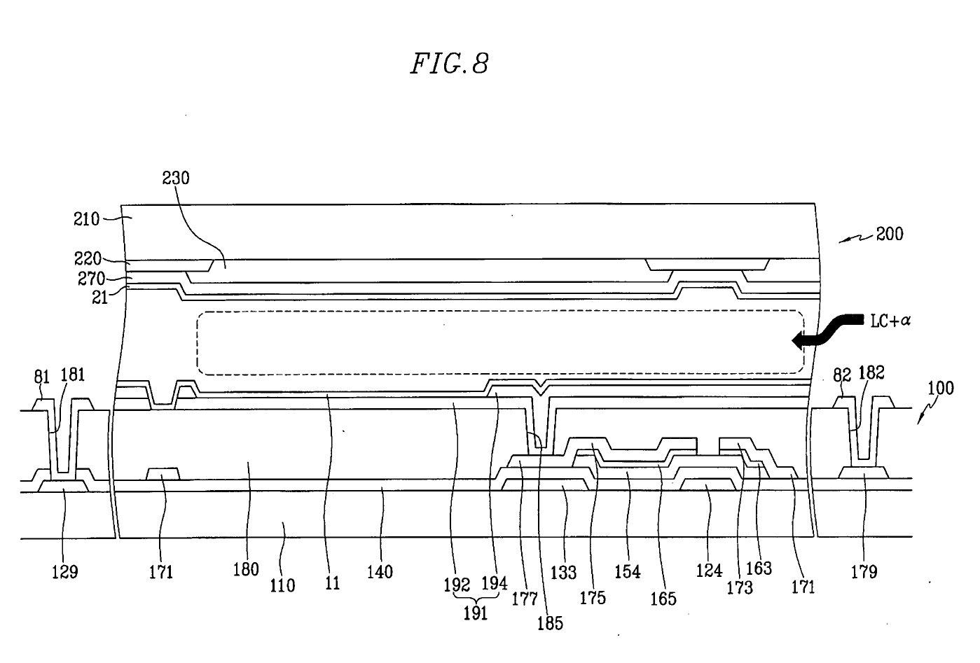

Hereinafter, an LCD according to an embodiment of the present invention will be described in detail with reference to FIG. 1 and FIG. 2.

A plurality of gate lines 121 and a plurality of storage electrode lines 131 are formed on an insulating substrate 110 made of transparent glass or plastic.

The gate lines 121 for transmitting gate signals extend substantially in a horizontal direction. Here horizontal direction refers to the horizontal direction as represented on FIG. 1. Each gate line 121 includes a plurality of gate electrodes 124 protruding upward and an end portion 129 having a relatively large dimension to be connected to a different layer or an external device (not shown). A gate driver (not shown) for generating the gate signals may be mounted on a flexible printed circuit (not shown) attached to the substrate 110, or directly on the substrate 110. Otherwise, the gate driver may be integrated into the substrate 110.

The storage electrode lines 131 for receiving a predetermined voltage extend substantially parallel to the gate lines 121. Each storage electrode line 131 is placed between two adjacent gate lines, and may be closer to the lower-positioned gate line of the two. Each storage electrode line 131 includes a plurality of expansions 133 protruding upward and downward. The form and arrangement of the storage electrode lines 131 may be freely varied.

The gate lines 121 and the storage electrode lines 131 can be made of an aluminum (Al)-containing metal such as Al or an Al alloy, a silver (Ag)-containing metal such as Ag or a Ag alloy, a gold(Au)-containing metal such as Au or a Au alloy, a copper (Cu)-containing metal such as Cu or a Cu alloy, a molybdenum (Mo)-containing metal such as Mo or a Mo alloy, chrome (Cr), titanium (Ti), or tantalum (Ta). The gate lines 121 may be configured as a double-layered structure, in which two conductive layers (not shown) having different physical properties are included. In the double-layered structure, one of the two layers is made of a low resistivity metal in order to reduce delay of the signals or voltage drop in the gate lines 121, and the other layer is made of a material having prominent physical, chemical, and electrical contact properties with other materials, such as indium tin oxide (ITO) and indium zinc oxide (IZO). Besides the above-listed materials, various metals and conductors can be used for the formation of the gate lines 121.

All lateral sides of the gate lines 121 and the storage electrode lines 131 can slope in the range from about 30° to 80° to the surface of the substrate 110.

A gate insulating layer 140, made of nitride silicon (SiNx) or oxide silicon (SiO₂), is formed on the gate lines 121 and the storage electrode lines 131.

A plurality of linear semiconductors 151, made of hydrogenated amorphous silicon (abbreviated as “a-Si”) or polysilicon, are formed on the gate insulating layer 140. Each linear semiconductor 151 extends substantially in a vertical direction, and includes a plurality of projections 154 that extend along the respective gate electrodes 124. Here vertical direction refers to the direction as represented on FIG. 1. The linear semiconductors 151 are enlarged in the vicinities of the gate lines 121 and the storage electrode lines 131 to sufficiently cover the gate lines and storage electrode lines.

A plurality of linear ohmic contacts 161 (not shown) and island-shaped ohmic contacts 165 are formed on the linear semiconductors 151. The ohmic contacts 161 and 165 may be made of N+ hydrogenated amorphous silicon that is highly doped with N-type impurities such as phosphorus (P), P+ hydrogenated amorphous silicon that is highly doped with P-type impurities such as boron (B), or silicide. The linear ohmic contacts 161 include a plurality of ohmic projections 163. A set of an ohmicprojection 163 and an island-shaped ohmic contact 165 are placed on the projection 154 of the semiconductor 151.

All lateral sides of the semiconductors 151 and the ohmic contacts 161 and 165 can slope in the range from about 30° to 80° to the surface of the substrate 110.

A plurality of data lines 171 and a plurality of drain electrodes 175 are formed on the ohmic contacts 161 and 165 and on the gate insulating layer 140.

The data lines 171 for transmitting data signals extend substantially in a vertical direction and cross the gate lines 121 and the storage electrode lines 131. Here vertical direction refers to the vertical direction as represented on FIG. 1. Each data line 171 includes a plurality of source electrodes 173 extending toward the respective gate electrodes 124, and an end portion 179 having a relatively large dimension to be connected to a different layer or an external device (not shown). A data driver (not shown) for generating the data signals may be mounted on a flexible printed circuit (not shown) attached to the substrate 110, or directly on the substrate 110. Otherwise, the data driver may be integrated into the substrate 110.

The drain electrodes 175 separated from the data lines 171 are opposite from the source electrodes 173, centering the gate electrodes 124. Each drain electrode 175 includes an expansion 177 with a main body and a bar-shaped end portion. The main body of the expansion 177 of the drain electrode 175 overlaps the expansion 133 of the storage electrode line 131, and the curved source electrode 173 partially surrounds the bar-shaped end portion of the expansion 177.

A gate electrode 124, a source electrode 173, a drain electrode 175, and a projection 154 of the semiconductor 151 form a thin film transistor (TFT). A TFT channel is formed in the projection 154 provided between the source electrode 173 and the drain electrode 175 and above the gate electrode 124.

The data lines 171 and the drain electrodes 175 can be made of a refractory metal, such as Mo, Cr, Ta, Ti, or alloys thereof, and may be configured as a multi-layered structure including a refractory metal layer (not shown) and a low resistivity conductive layer (not shown). One example of the multi-layered structure is a lower layer made of Cr, Mo, or Mo alloy, and an upper layer made of Al or an Al alloy. Another example is a lower layer made of Mo or Mo alloy, an intermediate layer made of Al or Al alloy, and an upper layer made of Mo or Mo alloy. Besides the above-mentioned examples, other combinations are possible.

All lateral sides of the data lines 171 and the drain electrodes 175 can slope from about 30° to 80° to the surface of the substrate 110.

The ohmic contacts 161 and 165 exist only between the underlying semiconductors 151 and the overlying data lines 171 and between the overlying drain electrodes 175 and the underlying semiconductors 151, in order to reduce contact resistance. Partial portions of the semiconductors 151 are enlarged in the vicinities of places to be crossed with the gate lines 121, as previously mentioned, to prevent the data lines 171 from being shorted. The linear semiconductors 151 are partially exposed at places where the data lines 171 and the drain electrodes 175 do not cover them, as well the region between the source electrodes 173 and the drain electrodes 175.

A passivation layer 180 is formed on the data lines 171, the drain electrodes 175, and the exposed portions of the semiconductors 151. The passivation layer 180 may be made of an inorganic insulator such as SiNx or SiO₂. The passivation layer 180 may also be made of an organic insulator or a low dielectric insulator, both having a dielectric constant of below 4.0. Examples of the low dielectric insulator include a-Si:C:O or a-Si:O:F, produced by plasma enhanced chemical vapor deposition (PECVD). The organic insulator may have desirable photosensitivity and planarization properties. Due to this insulator, the passivation layer 180 may have a flat surface. However, the passivation layer 180 may also be configured as a double-layered structure with a lower inorganic insulator layer and an upper organic insulator layer. This structure can improve the insulating property of the layer, thus reducing the potential for damage to the region of the semiconductor 154 that is not protected by the ohmic contacts.

The passivation layer 180 is provided with a plurality of contact holes 182 and 185, through which the end portions 179 of the data lines 171, and the drain electrodes 175 are exposed, respectively. A plurality of contact holes 181 are formed in the passivation layer 180 and the gate insulating layer 140, where the end portions 129 of the gate lines 121 are exposed.

A plurality of pixel electrodes 191 are formed on the passivation layer 180.

Each pixel electrode 191 is comprised of a transparent electrode 192 and a reflective electrode 194 overlying the transparent electrode 192.

In transflective LCDs, each pixel is divided into a transmission area TA and a reflection area RA. The reflection area RA is defined as the area of the pixel where the reflective electrode is formed. The transmission area TA is defined as the area of the pixel where only the transparent electrode is formed, and not the reflective electrode.

The transparent electrode 192 is a transparent conductor, such as ITO or IZO, and the reflective electrode 194 may be made of an opaque and reflective conductor such as Al, Al alloy, Cr, Ag, or Ag alloy.

Each pixel electrode 191 may be further comprised of a contact assistant (not shown) made of Mo, Mo alloy, Cr, Ti, or Ta. The contact assistant ensures contact properties between the transparent electrode 192 and the reflective electrode 194, while preventing the reflective electrode 194 from being oxidized by the transparent electrode 192.

The pixel electrodes 191 are physically and electrically connected to the expansions 177 of the drain electrodes 175 through the contact holes 185 in order to receive data voltages from the drain electrodes 175. The pixel electrodes 191 supplied with the data voltages generate an electric field in cooperation with the common electrode 270. The electric field determines the orientation of the liquid crystal molecules in the liquid crystal layer 3 interposed between the two electrodes 191 and 270.

Also, the pixel electrode 191 and the common electrode 270 together form a capacitor capable of storing the applied voltage after the TFT is turned off. This capacitor will be referred to as a “liquid crystal capacitor” below. To enhance the voltage storage ability, another capacitor, called a “storage capacitor”, is further provided. The storage capacitor is connected to the liquid crystal capacitor in parallel. The storage capacitor is implemented by overlapping the expansion 177 of the drain electrode 175 with the storage electrode line 131. The storage capacitor may also be implemented by overlapping the pixel electrode 191 with the gate line 121 adjacent thereto. Where the storage capacitor is included, the storage electrode line 131 may be omitted.

The pixel electrode 191 may be overlapped with the data line 171 adjacent thereto as well as the gate lines 121 adjacent thereto, in order to increase the aperture ratio, but such overlap portions are not essential.

The contact assistants 81 and 82 are provided to supplement adhesion between the exposed end portions 129 and 179 and exterior devices, and to protect them.

An alignment layer 11 is formed on the pixel electrodes 191 to uniformly align the liquid crystal molecules.

A plurality of light blocking elements 220, called black matrices, are provided on an insulating substrate 210, made of transparent glass or plastic, to prevent light from leaking out through barriers between the pixel electrodes 191 and to define aperture regions facing the pixel electrodes 191.

A plurality of color filters 230 are formed on the substrate 210. The color filters 230 are placed within the aperture regions defined by the light blocking elements 220. The color filters 230 extend along the pixel electrodes 191 substantially in a vertical direction, each exhibiting red, green, or blue colors.

A common electrode 270, made of a transparent conductive material such as ITO or IZO, is formed on the light blocking elements 220 and the color filters 230.

An alignment layer 21 is formed on the common electrode 270 to uniformly align the liquid crystal molecules.

Polarizers 12 and 22 may be individually attached to the outer surfaces of the insulating substrate 210 and insulating substrate 110, in order to control polarization axes parallel or perpendicularly. Either polarizer may be omitted.

The liquid crystal layer 3 is interposed between the TFT array panel 100 and the color filter panel 200 facing each other. The liquid crystal layer 3 comprises the liquid crystal molecules and polymers.

The liquid crystal molecules have positive dielectric anisotropy. In the absence of an electric field, they are aligned substantially parallel to the surfaces of the two panels 100 and 200.

The polymers are prepared by exposing photo-polymerizable monomers to light. Unlike the liquid crystal molecules, the polymers have optical isotropy. Accordingly, the polymers do not influence optical properties in the liquid crystal layer 3.

The transflective LCD includes the reflection areas RA and the transmission areas TA. In the reflection areas RA, incident light from the external environment passes through the liquid crystal layer 3 twice due to reflection, while in the transmission areas TA, incident light from an internal light source such as a backlight passes through the liquid crystal layer only once. Accordingly, to properly display the intended image, the areas TA and RA should have different phase retardation values. For example, when the transmission area TA has a phase retardation value of λ/2, the reflection area RA may have a phase retardation value of λ/4.

In the present invention, the differing values of the phase retardation in the TA and RA areas are obtained by varying the mixing ratio of the liquid crystal molecules and the polymers in the two areas. Specifically, the polymer concentration of the liquid crystal layer B corresponding to the reflection area RA is higher than the polymer concentration of the liquid crystal layer A corresponding to the transmission area TA. Conversely, the liquid crystal molecule content of the liquid crystal layer B is lower than the liquid crystal molecule content of the liquid crystal layer A. Thus, the reflection area RA has a lower phase retardation value than the transmission area TA, since the space occupied by the liquid crystal molecules within the liquid crystal layer B is substantially smaller than that of the liquid crystal layer A. Other methods can be used to vary the mixing ratio in the two areas TA and RA, such as exposing the two areas to light independently to vary the polymerization ratio.

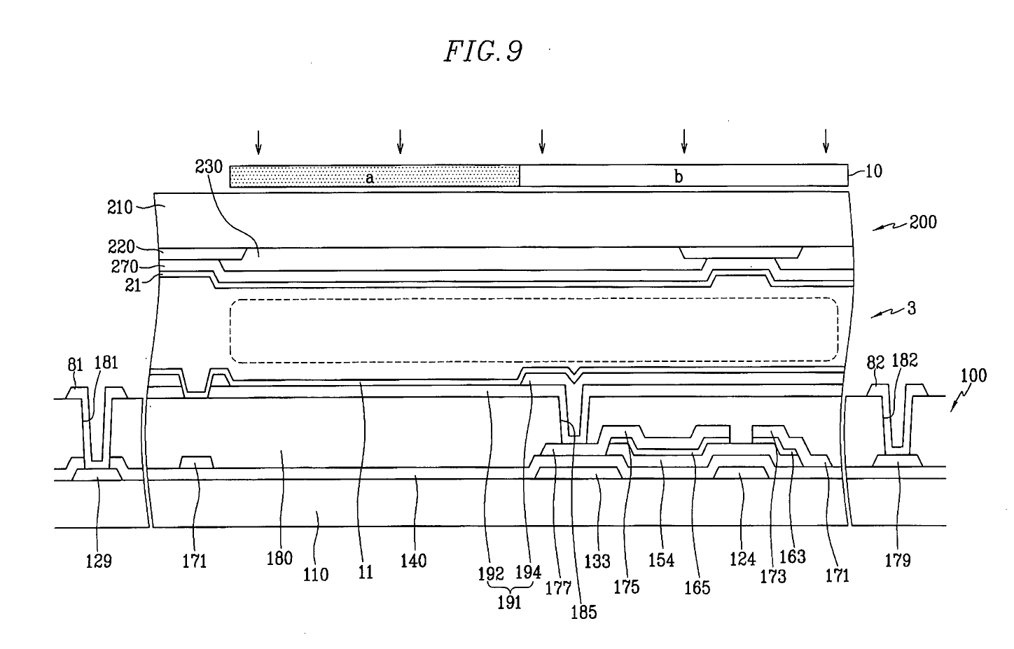

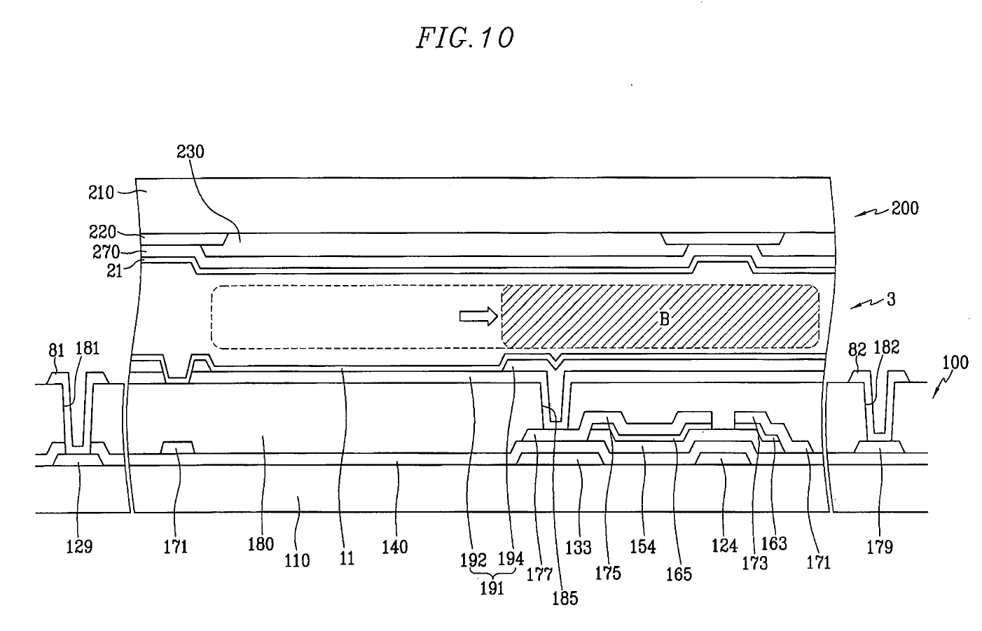

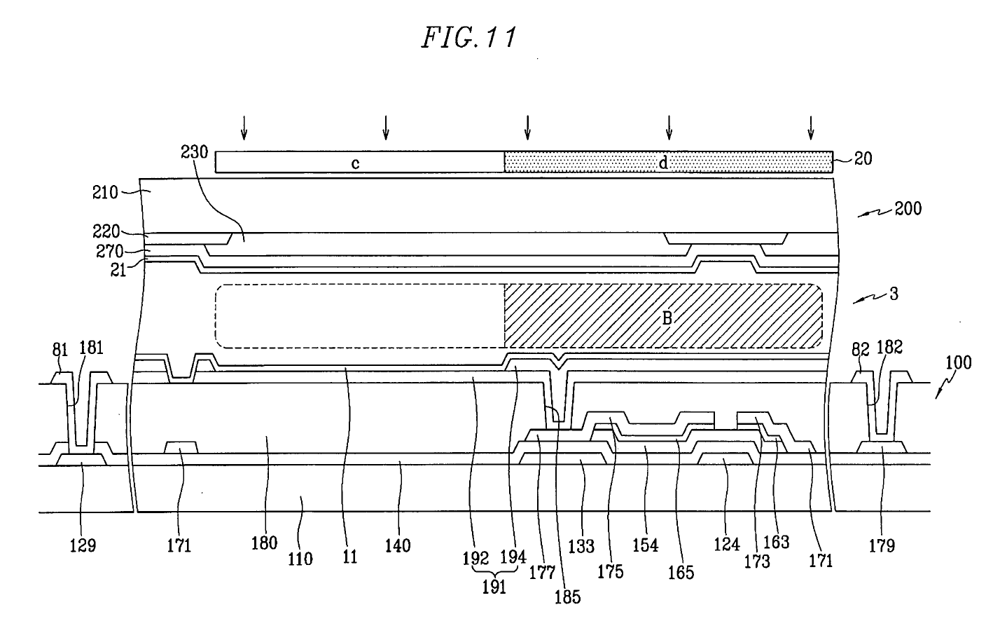

Hereinafter, a manufacturing method of the above-mentioned LCD will be described in detail with reference to FIG. 3, FIG. 4, FIG. 5, FIG. 6, FIG. 7, FIG. 8, FIG. 9, FIG. 10, and FIG. 11. FIG. 1 and FIG. 2 may be referenced as necessary.

The TFT array panel 100 is manufactured as follows.

A metal layer consisting of Al or an Al alloy, or Mo or a Mo alloy is first formed on an insulating substrate 110 made of transparent glass or plastic. The metal layer is selectively etched by photolithography using an etchant to form a plurality of gate lines 121 (not shown) with gate electrodes 124 and end portions 129, and a plurality of storage electrode lines 131 (not shown) with expansions 133, as shown in FIG. 3.

After the formation of the gate lines 121 and the storage electrode lines 131, a gate insulating layer 140, an intrinsic amorphous silicon layer, and a doped amorphous silicon layer are successively deposited on the resultant of FIG. 3 by plasma enhanced chemical vapor deposition (PECVD). The doped amorphous silicon layer and the intrinsic amorphous silicon layer are then selectively etched by photolithography, so that a plurality of linear and island-shaped impurity semiconductors 164, and a plurality of linear semiconductors 151 (not shown) with a plurality of projections 154 are formed as shown in FIG. 4. A possible material for the gate insulating layer 140 is nitride silicon (SiNx), the deposition temperature thereof is in the range of about 250° C. to 500° C., and a thickness thereof is in the range of about 2,000 Å to about 5,000 Å.

Next, a low resistivity metal layer made of, for example, an Al alloy or Mo alloy is formed on the resultant of FIG. 4. The metal layer is then selectively etched by photolithography using an etchant to form a plurality of data lines 171 with source electrodes 173 and end portions 179, and a plurality of drain electrodes 175 with expansions 177 and linear end portions surrounded with the curved source electrodes 173, as shown in FIG. 5.

Next, the exposed portions of the impurity semiconductors 164, which are not covered with the data lines 171 and the drain electrodes 175, are removed by dry etching. As a result, as shown in FIG. 5, a plurality of linear ohmic contacts 161 (not shown) with projections 163, and a plurality of island-shaped ohmic contacts 165 are completed, partially exposing the underlying linear semiconductors 151 (not shown). Subsequently, O₂ plasma process is performed to stabilize the exposed surfaces of the linear semiconductors 151.

Next, as shown in FIG. 6, a passivation layer 180 is deposited on the entire substrate 110, and is selectively etched by photolithography to form a plurality of contact holes 181, 182, and 185. After photolithography, the end portions 129 of the gate lines 121 and the end portions 179 of the data lines 171 are exposed through the contact holes 181, 182, and 185.

After the formation of the contact holes 181, 182, and 185, a transparent material such as ITO or IZO is deposited on the passivation layer 180. The deposited layer is then patterned using a mask, as shown in FIG. 7, thereby forming a plurality of transparent electrodes 192, connected to the expansions 177 of the drain electrodes 175 through the contact holes 185, and a plurality of contact assistants 82, connected to the end portions 179 of the data lines 171 through the contact holes 182, and a plurality of contact assistants 81, connected to the end portions 129 of the gate lines through the contact holes 181.

Next, an opaque metallic material with a higher reflectance, for example Cr, Al, Al alloy, Ag, or Ag alloy, is deposited on the transparent electrodes 192. The deposited metal layer is then patterned to remain only in the reflection ares RA. As a result, reflective electrode 194 is formed as shown in FIG. 7.

Next, as shown in FIG. 8, an alignment layer 11 is formed on the entire substrate 110 including the reflective electrode 194.

Meanwhile, the color filter panel 200, opposite the TFT array panel 100, is manufactured as follows.

First, a plurality of light blocking elements 220, separated from each other, are formed on an insulating substrate 210 made of transparent glass or plastic. Subsequently, a plurality of color filters 230 are formed in areas surrounded by the light-blocking elements 220. A common electrode 270 made of, for example, ITO or IZO is then formed on the light blocking elements 220 and the color filters 230. Then, an alignment layer 21 is formed on the common electrode 270.

After the color filter panel 200 is completed, the TFT array panel 100 and the color filter panel 200 are assembled with alignment layers 21 and 11 facing each other.

Next, as shown in FIG. 8, a mixture, represented as “LC+α”, of liquid crystal molecules and photo-polymerizable monomers is injected into a cell gap formed between the assembled panels 100 and 200.

Then, as shown in FIG. 9, a first mask 10 with transmission zone (b) and light shielding zone (a) is disposed on the color filter panel 200. The transmission zone (b) is disposed in a position corresponding to the reflection area RA, while the light shielding zone (a) is disposed in a position corresponding to the transmission area TA.

Then, an exposition process is performed. In this process, light is applied only to the reflection area RA corresponding to the transmission zone (b), so that only the monomers of the reflection area RA are polymerized. With the polymerization, the concentration of the monomers in the reflection area RA is remarkably reduced. Accordingly, the monomers of the transmission area TA diffuse into the reflection area RA, as shown in FIG. 10, and polymerization of the introduced monomers begins. As the monomers diffuse, the liquid crystal molecules of the reflection area RA diffuse to the transmission area TA. As a result, the reflection area RA obtains polymers in a higher concentration than that of the original LC+α mixture, while the transmission area TA obtains liquid crystal molecules in a higher concentration than that of the original LC+α mixture.

Then, as shown in FIG. 11, a second mask 20 with transmission zone (c) and light shielding zone (d) is disposed on the liquid crystal layer 3. The transmission zone (c) is disposed in a position corresponding to the transmission area TA, while the light shielding zone (d) is disposed in a position corresponding to the reflection areas TA.

Then, a second exposition process is performed. Light is applied only to the transmission area TA corresponding to the transmission zone (c), so that only the monomers of the transmission area TA are polymerized as shown in FIG. 2. As a result, the transmission area TA obtains the polymers in a lower concentration than that of the original LC+α mixture since since monomers from the transmission area TA diffused into the reflection areas RA during the previous stage.

As thus described, in the present invention involving a transreflective LCD, the phase retardation values of the transmission areas and reflection areas are varied by varying the mixing ratio of the liquid crystal molecules and the polymers while maintaining the same cell gap in the two areas.

It will be apparent to those skilled in the art that various modifications and variation can be made in the present invention without departing from the spirit or scope of the invention. Thus, it is intended that the present invention cover the modifications and variations of this invention provided they come within the scope of the appended claims and their equivalents.

What is claimed is:

1. A transflective liquid crystal display, comprising:
a first substrate;
a gate line formed on the first substrate;
a data line insulated from and intersecting the gate line;
a thin film transistor coupled to the gate line and the data line;
a transparent electrode coupled to the thin film transistor;
a reflective electrode formed on the transparent electrode;
a second substrate opposite to the first substrate that comprises a common electrode; and
a liquid crystal layer that comprises liquid crystal molecules and polymers and is interposed between the first substrate and the second substrate;
wherein a reflection area is formed around the reflective electrode, a transmission area is formed around the transparent electrode and not around the reflective electrode, and the ratio of the liquid crystal molecules to the polymers contained in the liquid crystal layer is different in the transmission area and the reflection area.

2. The transreflective liquid crystal display of claim 1, wherein the ratio of the liquid crystal molecules to the polymers contained in the liquid crystal layer is higher in the transmission area than in the reflection area.

3. The transreflective liquid crystal display of claim 2, wherein the density of liquid crystal molecules in the transmission area is higher than the density of liquid crystal molecules in the reflection area.

4. The transreflective liquid crystal display of claim 2, wherein the density of polymers in the transmission area is lower than the density of polymers in the reflection area.

5. The transflective liquid crystal display of claim 1, wherein the transmission area has a cell gap substantially similar to the cell gap in the reflection area.

6. The transflective liquid crystal display of claim 1, wherein the transmission area has a phase retardation value higher than the phase retardation value of the reflection area.

7. The transflective liquid crystal display of claim 6, wherein the transmission area has a phase retardation value of λ/2 and the reflection area has a phase retardation value of λ/4.

8. The transflective liquid crystal display of claim 1, wherein the polymers are polymerized from photo-polymerizable monomers.

9. The transflective liquid crystal display of claim 1, wherein the transparent electrode comprises ITO or IZO.

10. The transflective liquid crystal display claim 1, wherein the reflective electrode comprises aluminum, aluminum alloy, silver, silver alloy, or chrome.

11. A method for manufacturing a transflective liquid crystal display, comprising:
forming a gate line on a first substrate;
forming a gate insulating layer and a semiconductor on the gate line;
forming a data line on the gate insulating layer and the semiconductor;
forming a transparent electrode on the data line;
forming a reflective electrode on the transparent electrode;
forming a color filter and a common electrode on a second substrate;
assembling the first substrate and the second substrate;
injecting a mixture comprising liquid crystal molecules and monomers between the first substrate and the second substrate; and
exposing the reflective electrode and the mixture around the reflective electrode to light, and then exposing the transparent electrode and the mixture around the transparent electrode to light.

12. The method of claim 11, wherein the monomers comprise photo-polymerizable monomers.

13. The method of claim 12, wherein exposing the reflection area to light comprises:
polymerizing the monomers in the reflection area to yield polymers; and
diffusing monomers from the transmission area to the reflection area.

14. The method of claim 11, wherein exposing the transmission area to light yields a lower concentration of polymers in the transmission area than in the reflection area.

15. The method of claim 11, wherein after the completion of all steps, the transmission area comprises a mixture of liquid crystal molecules and polymers in a ratio different from the ratio in the reflection area.

16. A liquid crystal layer of a liquid crystal display (LCD), comprising:
liquid crystal molecules; and
polymers;
wherein a ratio of the liquid crystal molecules to the polymers contained in an area around a transparent electrode is higher than in an area around a reflective electrode.

17. The liquid crystal layer of claim 16, wherein the area around a reflective electrode has a lower phase retardation value than the area around a transparent electrode.

18. The liquid crystal layer of claim 17, wherein the area around a reflective electrode has a substantially similar cell gap as the area around a transparent electrode.
